(19) United States
(12) Patent Application Publication
(10) Pub. No.: US 2020/0402959 A1
(43) Pub. Date: Dec. 24, 2020

(54) STACKED SEMICONDUCTOR PACKAGE HAVING AN INTERPOSER

(71) Applicant: SK hynix Inc., Icheon-si Gyeonggi-do (KR)

(72) Inventors: Ju Il EOM, Yongin-si Gyeonggi-do (KR); Jae Hoon LEE, Icheon-si Gyeonggi-do (KR); Sang Joon LIM, Icheon-si Gyeonggi-do (KR)

(73) Assignee: SK hynix Inc., Icheon-si Gyeonggi-do (KR)

(21) Appl. No.: 16/660,671

(22) Filed: Oct. 22, 2019

(30) Foreign Application Priority Data
Jun. 21, 2019 (KR) 10-2019-0074338

(51) Int. Cl. H01L 25/065; H01L 23/538; H01L 23/00

(52) U.S. Cl. CPC H01L 25/0657; H01L 23/5385; H01L 24/06; H01L 23/5384; H01L 23/5386

(57) ABSTRACT

A semiconductor package according to an aspect of the present disclosure includes a package substrate, a lower chip, an interposer, and an upper chip sequentially stacked on the package substrate, and bonding wires electrically connecting the package substrate and the interposer. The interposer includes lower chip connection pads electrically connected to the lower chip on a lower surface of the interposer, first upper chip connection pads and second upper chip connection pads electrically connected to the upper chip, respectively, on an upper surface of the interposer, wire bonding pads disposed on the upper surface of the interposer and bonded to the bonding wires, first redistribution lines disposed on the upper surface of the interposer and electrically connecting the second upper chip connection pads to the wire bonding pads, and through via electrodes electrically connecting the lower chip connection pads and the first upper chip connection pads.

### CROSS-REFERENCE TO RELATED APPLICATION

The present application claims priority under 35 U.S.C 119(a) to Korean Patent Application No. 10-2019-0074338, filed on Jun. 21, 2019, which is incorporated herein by reference in its entirety.

### BACKGROUND

### 1. Technical Field

The present disclosure relates generally to semiconductor packages and, more particularly, to stacked semiconductor packages including an interposer.

### 2. Related Art

In general, semiconductor packages may be configured to include a substrate and a semiconductor chip mounted on the substrate. The semiconductor chip can be electrically connected to the substrate through connection members such as bumps or wires.

Recently, in accordance with a demand for semiconductor packages with high performance and high integration, various ways of stacking a plurality of semiconductor chips on a substrate have been proposed. For example, a technique of electrically connecting a plurality of semiconductor chips stacked on a substrate using through silicon vias (TSVs) has been proposed.

### SUMMARY

According to an embodiment of the present disclosure, a semiconductor package may include a package substrate, a lower chip, an interposer, and an upper chip sequentially stacked on the package substrate, and include bonding wires electrically connecting the package substrate and the interposer. The interposer includes lower chip connection pads disposed on a lower surface of the interposer, wherein the lower chip connection pads are electrically connected to the lower chip. The interposer also includes first upper chip connection pads and second upper chip connection pads disposed on an upper surface of the interposer, wherein the first upper chip connection pads and the second upper chip connection pads are electrically connected to the upper chip. The interposer further includes wire bonding pads disposed on the upper surface of the interposer and bonded to the bonding wires, first redistribution lines disposed on the upper surface of the interposer and electrically connecting the second upper chip connection pads to the wire bonding pads, and through via electrodes electrically connecting the lower chip connection pads to the first upper chip connection pads.

According to another embodiment of the present disclosure, a stacked semiconductor package may include a package substrate, a lower chip, an interposer, and an upper chip sequentially stacked on the package substrate, and bonding wires electrically connecting the package substrate and the interposer. The interposer includes through via electrodes electrically connecting the lower chip to the upper chip, and a first redistribution lines electrically connecting the upper chip to the bonding wires.

### BRIEF DESCRIPTION OF THE DRAWINGS

FIG. 1 is a cross-sectional view illustrating a semiconductor package according to an embodiment of the present disclosure.

FIG. 2 is a plan view illustrating a semiconductor chip according to an embodiment of the present disclosure.

FIG. 3 is a plan view illustrating a semiconductor chip according to an embodiment of the present disclosure.

FIGS. 4A, 4B, and 4C are views illustrating an interposer according to an embodiment of the present disclosure.

FIG. 5 is a schematic view illustrating a method of exchanging electrical signals between a semiconductor chip and a package substrate according to an embodiment of the present disclosure.

FIG. 6 is a view illustrating an internal circuit configuration of a semiconductor package according to an embodiment of the present disclosure.

### DETAILED DESCRIPTION

The terms used herein may correspond to words selected in consideration of their functions in the embodiments, and the meanings of the terms may be construed to be different according to ordinary skill in the art to which the embodiments belong. If defined in detail, the terms may be construed according to the definitions. Unless otherwise defined, the terms (including technical and scientific terms) used herein have the same meaning as commonly understood by one of ordinary skill in the art to which the embodiments belong.

It will be understood that although the terms “first,” “second,” “third” etc. may be used herein to describe various elements, these elements should not be limited by these terms. These terms are only used to distinguish one element from another element, and are not used to imply a particular sequence or number of elements. It will also be understood that when an element or layer is referred to as being “on,” “over,” “below,” “under,” or “outside” another element or layer, the element or layer may be in direct contact with the other element or layer, or intervening elements or layers may be present. Other words used to describe the relationship between elements or layers should be interpreted in a like fashion (e.g., “between” versus “directly between” or “adjacent” versus “directly adjacent”).

Spatially relative terms, such as “beneath,” “below,” “lower,” “above,” “upper,” “top,” “bottom” and the like, may be used to describe an element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, when the device in the figures is turned over, elements described as below and/or beneath other elements or features would then be oriented above the other elements or features. The device may be otherwise oriented (rotated 90 degrees or at other orientations) and the spatially relative descriptors used herein interpreted accordingly.

A semiconductor package described herein may include electronic devices such as semiconductor chips. The semiconductor chips may be obtained by separating a semiconductor substrate such as a wafer into a plurality of pieces using a die sawing process. The semiconductor chips may correspond to memory chips, logic chips (including application specific integrated circuits (ASIC) chips), or system-on-chips (SoC). The memory chips may include dynamic random access memory (DRAM) circuits, static random access memory (SRAM) circuits, NAND-type flash memory circuits, NOR-type flash memory circuits, magnetic random access memory (MRAM) circuits, resistive random access memory (ReRAM) circuits, ferroelectric random access memory (FeRAM) circuits or phase change random access memory (PcRAM) circuits which are integrated on the semiconductor substrate. The logic chips may include logic circuits which are integrated on the semiconductor substrate. The semiconductor chips may be referred to as semiconductor dies according to their shape after the die sawing process.

The semiconductor package may include a package substrate on which the semiconductor chip is mounted. The package substrate may include at least one layer of integrated circuit patterns and may be referred to as a printed circuit board (PCB) in the present specification.

The semiconductor package may, as an embodiment, include a plurality of semiconductor chips mounted on the package substrate. In the semiconductor package, any one of the plurality of semiconductor chips may be set as a master chip and the remaining semiconductor chips may be set as a slave chip. Then, the memory cells of the slave chip may be controlled using the master chip. The mast chip may directly exchange signals with the package substrate, and the slave chip may exchange signals with the package substrate through the mast chip.

The semiconductor package may be employed in various communication systems such as mobile phones, electronic systems associated with biotechnology or health care, or wearable electronic systems.

Same reference numerals refer to same elements throughout the specification. Even though a reference numeral is not mentioned or described with reference to a drawing, the reference numeral may be mentioned or described with reference to another drawing. In addition, even though a reference numeral is not shown in a drawing, it may be mentioned or described with reference to another drawing.

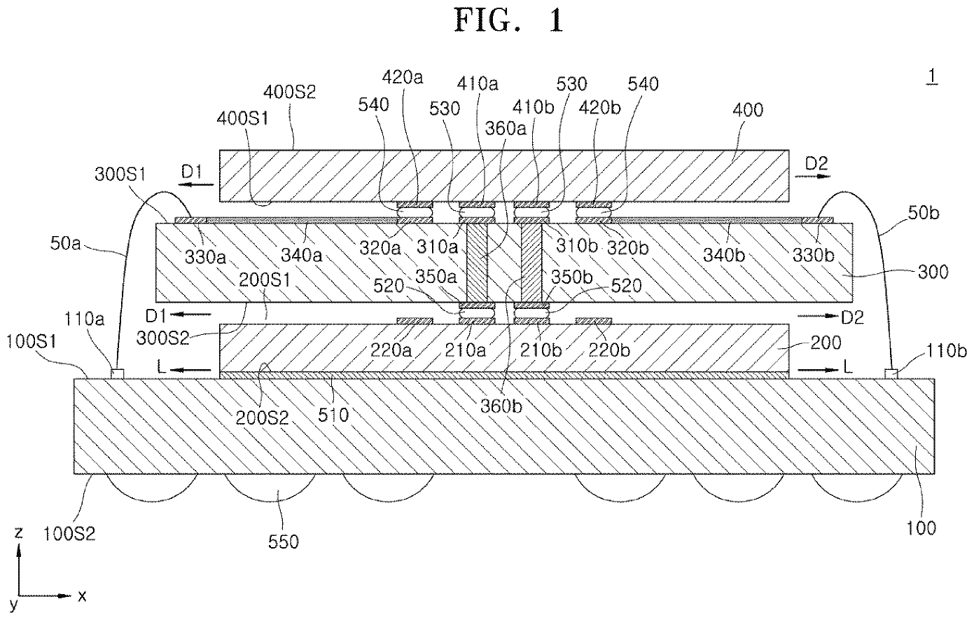

FIG. 1 is a cross-sectional view illustrating a semiconductor package 1 according to an embodiment of the present disclosure.

Referring to FIG. 1, the semiconductor package 1 may include a lower chip 200, an interposer 300, and an upper chip 400 stacked on a package substrate 100. The interposer 300 may be electrically connected to the package substrate 100 using bonding wires 50a and 50b.

The lower chip 200 and the upper chip 400 may each be a semiconductor chip including an integrated circuit. The upper chip 400 may be electrically connected to the package substrate 100 using first redistribution lines 340a and 340b and the bonding wires 50a and 50b. Meanwhile, the lower chip 200 may be electrically connected to the upper chip 400 using through via electrodes 360a and 360b in the interposer 300. That is, the upper chip 400 may exchange electrical signals with the package substrate 100 through the first redistribution lines 340a and 340b and the bonding wires 50a and 50b, and the lower chip 200 may exchange electrical signals with the package substrate 100 through the upper chip 400.

Referring to FIG. 1, the package substrate 100 is provided. The package substrate 100 may have an upper surface 100S1 and a lower surface 100S2 that is opposite to the upper surface 10051. Although not shown in FIG. 1, the package substrate 100 may include at least one layer of integrated circuit patterns.

Connection pads 110a and 110b for wire bonding with the interposer 300 may be disposed on the upper surface 10051 of the package substrate 100. Moreover, connection structures 550 for electrical connection with other semiconductor packages or PCBs may be disposed on the lower surface 100S2 of the package substrate 100. The connection structures 550 may include, for example, bumps, solder balls, or the like.

The lower chip 200 may be disposed on the package substrate 100. The lower chip 200 may have an upper surface 200S1 and a lower surface 200S2. First lower chip pads 210a and 210b and second lower chip pads 220a and 220b may be disposed on the upper surface 200S1 of the lower chip 200. Each of the first lower chip pads 210a and 210b may be connected to lower chip connection pads 350a and 350b of the interposer 300, respectively, by first bumps 520. The second lower chip pads 220a and 220b may be disposed apart from the first lower chip pads 210a and 210b in a lateral direction (i.e., an x-direction) and might not participate in the lateral connection with the interposer 300. Meanwhile, a non-conductive adhesive layer 510 may be disposed on the lower surface 200S2 of the lower chip 200, so that the lower chip 200 can be bonded to the package substrate 100.

The interposer 300 may be disposed over the lower chip 200. The interposer 300 may have an upper surface 300S1 and a lower surface 300S2. The lower chip connection pads 350a and 350b electrically connected to the lower chip 200 may be disposed on the lower surface 300S2 of the interposer 300. In an embodiment, the lower chip connection pads 350a and 350b may be connected to the first lower chip pads 210a and 210b, respectively, by the first bumps 520. First upper chip connection pads 310a and 310b and second upper chip connection pads 320a and 320b, which are electrically connected to the upper chip 400, may be disposed on the upper surface 300S1 of the interposer 300.

The interposer 300 may include at least one region that protrudes from the edge region of the upper chip 400 in lateral directions (i.e., the D1 and D2 directions). Accordingly, as an example, a width of the interposer 300 along the x-direction may be greater than a width of the upper chip 400 along the x-direction. Wire bonding pads 330a and 330b may be disposed on the regions of the interposer 300 that protrude or extend in the lateral direction beyond the upper chip 400. The wire bonding pads 330a and 330b may be electrically connected to the lower chip connection pads 110a and 110b on the package substrate 100 by the bonding wires 50a and 50b. Meanwhile, first redistribution lines 340a and 340b for connecting the second upper chip connection pads 320a and 320b to the wire bonding pads 330a and 330b may be disposed on the upper surface 300S1 of the interposer 300. The second upper chip connection pads 320a and 320b are electrically connected to the second upper chip pads 420a and 420b of the upper chip 400, so that the upper chip 400 is electrically connected to the package substrate 100 through the first redistribution lines 340a and 340b and the bonding wires 50a and 50b.

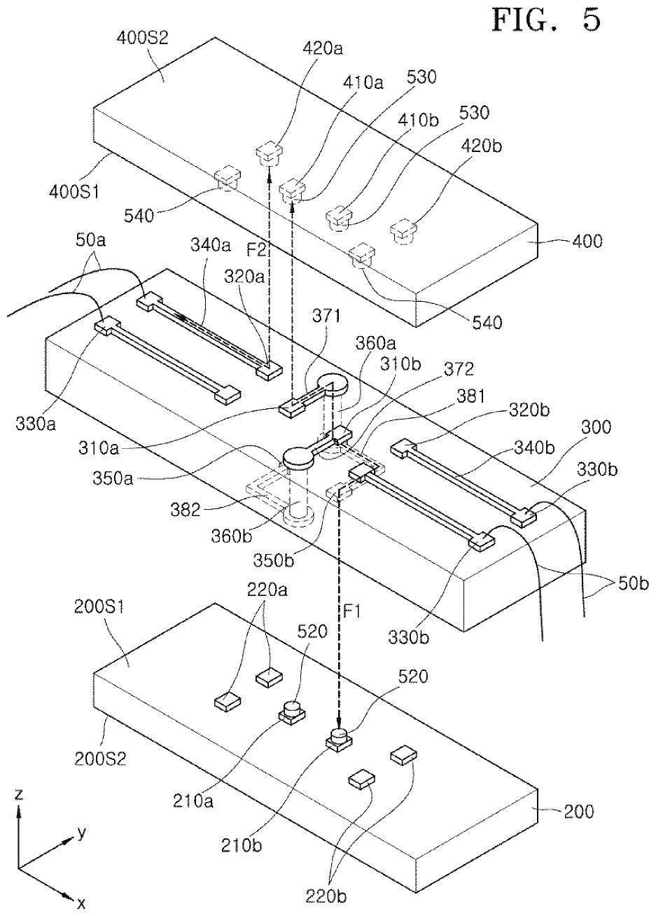

The interposer 300 may include the through via electrodes 360a and 360b for electrically connecting the first upper chip connection pads 310a and 310b to the lower chip connection pads 350a and 350b, respectively. In an embodiment, as described below with reference to FIG. 5, the interposer 300 may further include second to fifth wiring layers 371, 372, 381, and 382 disposed on the upper surface 300S1 and the lower surface 300S2 of the interposer 300 in order to connect the first upper chip connection pads 310a and 310b and the lower chip connection pads 350a and 350b to the through via electrodes 360a and 360b, respectively.

The upper chip 400 may be disposed over the interposer 300. The upper chip 400 may have an upper surface 400S1 and a lower surface 400S2. First upper chip pads 410a and 410b and second upper chip pads 420a and 420b may be disposed on the upper surface 400S1 of the upper chip 400, which faces the interposer 300. The first upper chip pads 410a and 410b may be connected to the first upper chip connection pads 310a and 310b of the interposer 300, respectively, by second bumps 530. The second upper chip pads 420a and 420b may be disposed apart from the first upper chip pads 410a and 410b in a lateral direction (i.e., the x-direction) and may be connected to the second upper chip connection pads 320a and 320b of the interposer 300, respectively, by third bumps 540. In an embodiment, each of the first upper chip pads 410a and 410b may have substantially the same size as the second upper chip pads 420a and 420b. In an embodiment, the second bumps 530 and the third bumps 540 may have substantially the same size.

In an embodiment, each of the lower chip 200 and the upper chip 400 may be a memory chip. In an embodiment, the lower chip 200 and the upper chip 400 may be chips having the same structure. In an embodiment, the upper chip 400 may be a master chip and the lower chip 200 may be a slave chip. The upper chip 400 may be electrically connected to the package substrate 100 through the first redistribution lines 340a and 340b of the interposer 300 and the bonding wires 50a and 50b. The lower chip 200 may be electrically connected to the package substrate 100 through the upper chip 400 by way of the through via electrodes 360a and 360b. Accordingly, the lower chip 200 may share an input/output circuit of the upper chip 400.

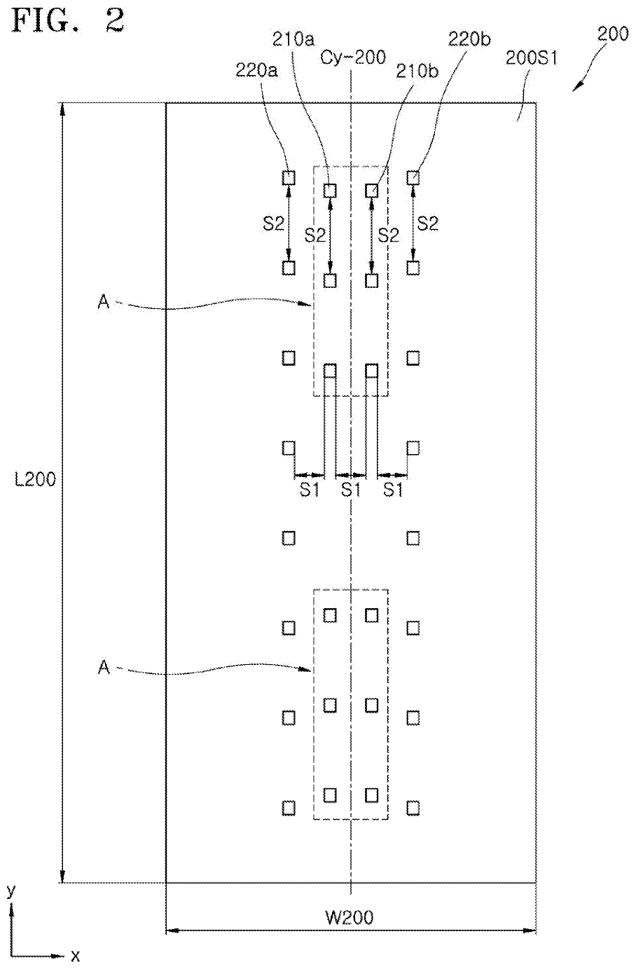

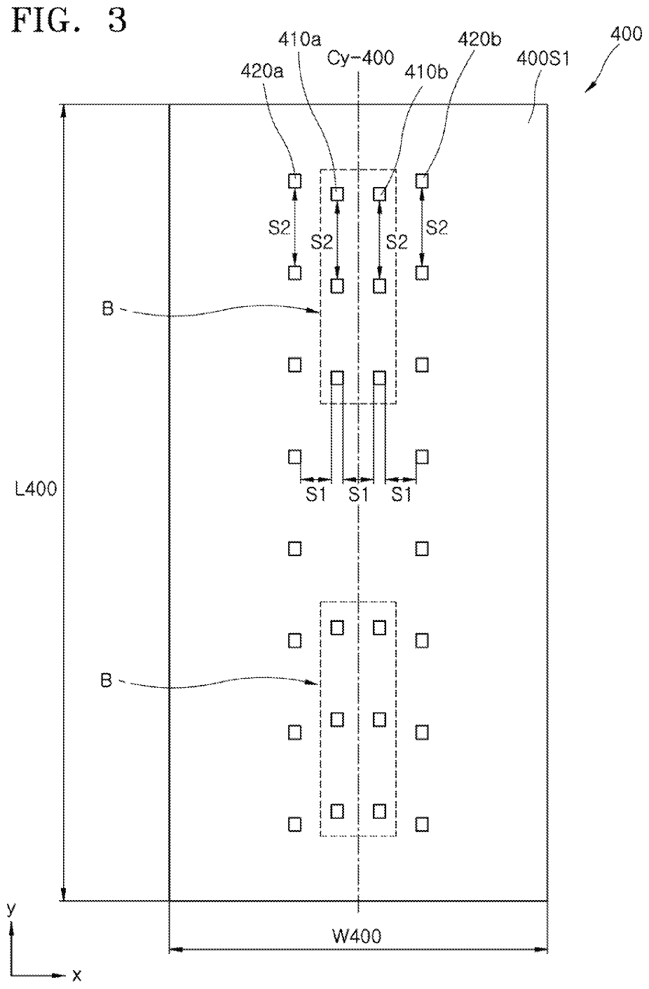

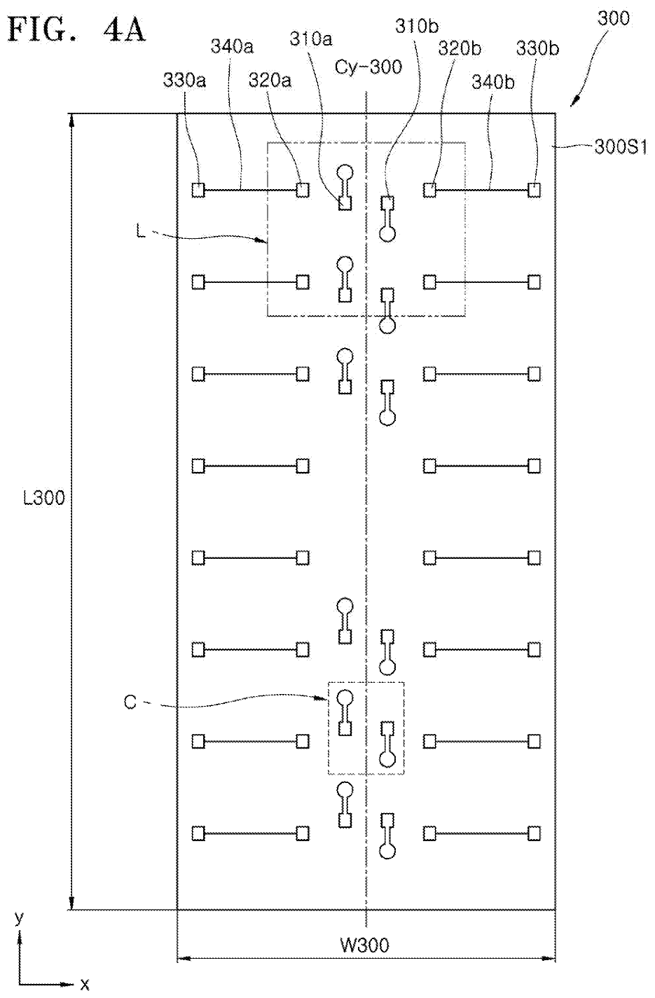

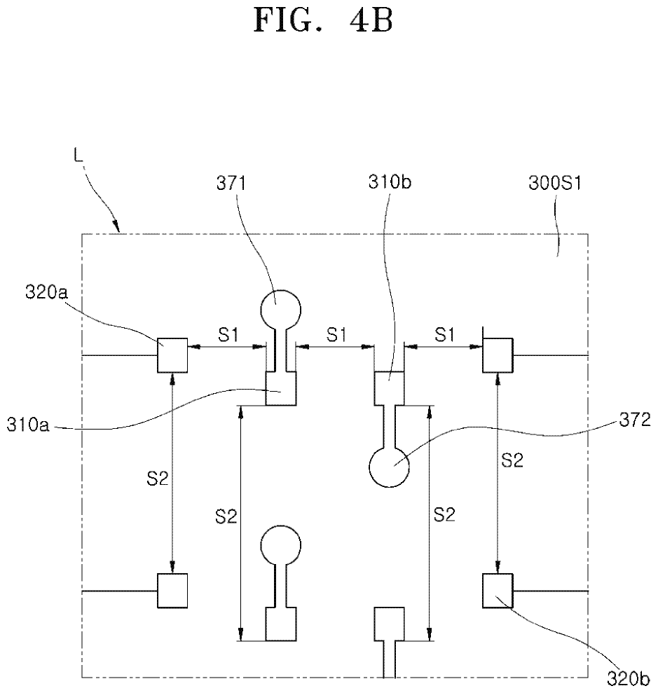

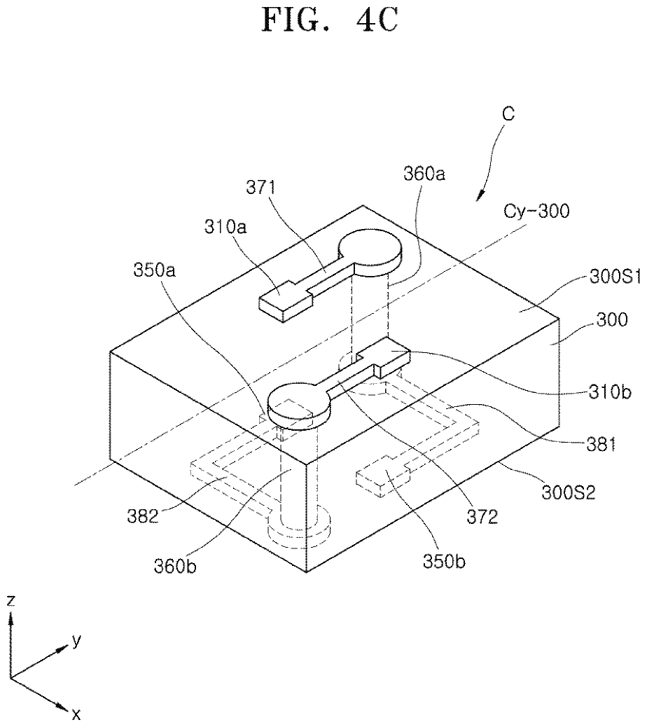

FIGS. 2 and 3 are plan views illustrating semiconductor chips according to an embodiment of the present disclosure. More specifically, FIG. 2 illustrates the lower chip 200 of FIG. 1, and FIG. 3 illustrates the upper chip 400 of FIG. 1. FIGS. 4A, 4B, and 4C are views illustrating an interposer according to an embodiment of the present disclosure. More specifically, FIG. 4A is a plan view illustrating the interposer 300 of FIG. 1, FIG. 4B is a partially enlarged view of portion “L” of FIG. 4A, and FIG. 4C is a perspective view of the through via arrangement region “C” of FIG. 4A.

Referring to FIG. 2, the lower chip 200 may have a minor axis along the x-direction and a major axis along the y-direction. In addition, the lower chip 200 may have a central axis Cy-200 parallel with the major axis. The lower chip 200 may have a width W200 in the minor axis direction and a length L200 in the major axis direction. The central axis Cy-200 may extend such that half the width W200 of the lower chip 200 is on either side of the central axis Cy-200.

First lower chip pads 210a and 210b and second lower chip pads 220a and 220b may be arranged in the major axis direction (i.e., the y-direction). The first lower chip pads 210a and 210b and the second lower chip pads 220a and 220b may be disposed to form symmetrical pairs with respect to the central axis Cy-200, respectively. In a specific embodiment, the first lower chip pads 210a and 210b may be disposed closer to the central axis Cy-200 than the second lower chip pads 220a and 220b. The first lower chip pads 210a and 210b may be classified as a first lower chip left pad 210a and a first lower chip right pad 210b with respect to the central axis Cy-200. The second lower chip pads 220a and 220b may be classified as a second lower chip left pad 220a and a second lower chip right pad 220b with respect to the central axis Cy-200.

As illustrated in FIG. 2, a surface area of each of the first lower chip pads 210a and 210b may be substantially the same as a surface area of each of the second lower chip pads 220a and 220b. As an example, the first lower chip pads 210a and 210b and the second lower chip pads 220a and 220b may have the same shape and size. Here, the rows of the first lower chip pads 210a and 210b and the rows of the second lower chip pads 220a and 220b may be arranged at the same horizontal interval S1 in the x-direction. As illustrated in FIG. 2, the second lower chip left pad 220a, the first lower chip left pad 210a, the first lower chip right pad 210b, and the second lower chip right pad 220b may be sequentially arranged at the same horizontal interval S1. In addition, the first lower chip pads 210a and 210b and the second lower chip pads 220a and 220b may be arranged at the same vertical interval S2 in the y-direction.

Referring to FIGS. 1 and 2, the first lower chip pads 210a and 210b may be electrically connected to the upper chip 400 through the through via electrodes 360a and 360b. That is, the first lower chip pads 210a and 210b may act as signal input/output pads of the lower chip 200 for exchanging electrical signals with the upper chip 400. The first lower chip pads 210a and 210b may be arranged in a concentrated manner in a through via electrode arrangement region A on the upper surface 20051 of the lower chip 200. The second lower chip pads 220a and 220b may be continuously disposed at the same vertical interval S2 in the central axis Cy-200. Meanwhile, the second lower chip pads 220a and 220b of the lower chip 200 might not be electrically connected to other structures, such as the interposer 300 and the package substrate 100.

Referring to FIG. 3, the upper chip 400 may have a minor axis in the x-direction and a major axis in the y-direction. In addition, the upper chip 400 may have a central axis Cy-400 parallel with the major axis. The upper chip 400 may have a width W400 in the minor axis direction and may have a length L400 in the major axis direction. The central axis Cy-400 may extend such that half of the width W400 of the upper chip 400 is on either side of the central axis Cy-400.

The first upper chip pads 410a and 410b and the second upper chip pads 420a and 420b may be arranged on the upper surface 400S1 of the upper chip 400 in the major axis direction (i.e., the y-direction). The first upper chip pads 410a and 410b and the second upper chip pads 420a and 420b may be disposed to form symmetrical pairs with respect to the central axis Cy-400, respectively. In a specific example, the first upper chip pads 410a and 410b may be disposed closer to the central axis Cy-400 than the second upper chip pads 420a and 420b. The first upper chip pads 410a and 410b may be classified as a first upper chip left pad 410a and a first upper chip right pad 410b with respect to the central axis Cy-400. The second upper chip pads 420a and 420b may be classified as a second upper chip left pad 420a and a second upper chip right pad 420b with respect to the central axis Cy-400.

As illustrated in FIG. 3, a surface area of each of the first upper chip pads 410a and 410b may be substantially the same as a surface area of each of the second upper chip pads 420a and 420b. As an example, the first upper chip pads 410a and 410b and the second upper chip pads 420a and 420b may have the same shape and size. Here, the rows of the first upper chip pads 410a and 410b and the rows of the second upper chip pads 420a and 420b may be arranged at the same horizontal interval S1 in the x-direction. As illustrated in FIG. 3, the second upper chip left pad 420a, the first upper chip left pad 410a, the first upper chip right pad 410b, and the second upper chip right pad 420b may be sequentially arranged at the same horizontal interval S1. In addition, the first upper chip pads 410a and 410b and the second upper chip pads 420a and 420b may be arranged at the same vertical interval S2 in the y-direction.

Referring to FIGS. 1 and 3, the first upper chip pads 410a and 410b may be electrically connected to the lower chip 200 through the through via electrodes 360a and 360b. That is, the first upper chip pads 410a and 410b may act as signal input/output pads of the upper chip 400 for exchanging electrical signals with the lower chip 200. The first upper chip pads 410a and 410b may be arranged in a concentrated manner in a through via electrode arrangement region B on the upper surface 40051 of the upper chip 400. The second upper chip pads 420a and 420b may be continuously disposed at the same vertical interval S2 in the central axis Cy-400. The second upper chip pads 420a and 420b of the upper chip 400 may be electrically connected to the second upper chip connection pads 320a and 320b of the interposer 300. That is, the second upper chip pads 420a and 420b may act as signal input/output pads of the upper chip 400 for exchanging electrical signals with the interposer 300 and the package substrate 100.

Referring to FIGS. 4A to 4C, the interposer 300 may have a minor axis in the x-direction and a major axis in the y-direction. In addition, the interposer 300 may have a central axis Cy-300 parallel with the major axis. The interposer 300 may have a width W300 in the minor axis direction and may have a length L300 in the major axis direction. The central axis Cy-300 may extend such that half the width W300 of the interposer 300 is on either side of the central axis Cy-300.

The first upper chip connection pads 310a and 310b, the second upper chip connection pads 320a and 320b, and wire bonding pads 330a and 330b may be arranged on the upper surface 300S1 of the interposer 300 in the major axis direction (i.e., the y-direction). In an embodiment, the first upper chip connection pads 310a and 310b, the second upper chip connection pads 320a and 320b, and the wire bonding pads 330a and 330b may be disposed to form symmetrical pairs with respect to the central axis Cy-300, respectively. In a specific example, the first upper chip connection pads 310a and 310b, the second upper chip connection pads 320a and 320b, and the wire bonding pads 330a and 330b may be sequentially disposed from the central axis Cy-300 of the interposer 300 in the x-direction. As illustrated, a surface area of each of the first upper chip connection pads 310a and 310b, the second upper chip connection pads 320a and 320b, and the wire bonding pads 330a and 330b may be substantially the same. As an example, the first upper chip connection pads 310a and 310b, the second upper chip connection pads 320a and 320b, and the wire bonding pads 330a and 330b may have the same shape and size.

Meanwhile, the first upper chip connection pads 310a and 310b may be classified as a first upper left pad 310a and a first upper right pad 310b that are symmetrical to each other with respect to the central axis Cy-300. Here, second redistribution lines 371 connected to the first upper left pad 310a and third redistribution lines 372 connected to the first upper right pad 310b may be disposed on the upper surface 300S1 of the interposer 300 in the y-direction. As described below with reference to FIGS. 4C and 5, the second redistribution line 371 may connect the first upper left pad 310a to the first through via electrode 360a, and the third redistribution line 372 may connect the first upper right pad 310b to the second through via electrode 360b. The wire bonding pads 330a and 330b may be classified as a left wire bonding pad 330a and a right wire bonding pad 330b that are symmetrical to each other with respect to the central axis Cy-300.

Meanwhile, the first upper chip connection pads 310a and 310b may be connected to the first upper chip pads 410a and 410b, respectively, by the second bumps 530.

The lower chip connection pads 350a and 350b may be disposed on the lower surface 300S2 of the interposer 300. The lower chip connection pads 350a and 350b may be connected to the first lower chip pads 210a and 210b of the lower chip 200, respectively, by the first bumps 520. Meanwhile, the lower chip connection pads 350a and 350b may be classified as a lower left pad 350a and a lower right pad 350b that are symmetrical to each other with respect to the central axis Cy-300. Here, a fifth redistribution lines 382 connected to the lower left pad 350a and a fourth redistribution line 381 connected to the lower right pad 350b may be disposed on the lower surface 300S2 of the interposer 300.

The lower left pad 350a may be connected to the second through via electrode 360b on the lower surface 300S2 of the interposer 300 by the fifth redistribution line 382. In addition, the lower right pad 350b may be connected to the first through via electrode 360a by the fourth redistribution line 381. In an embodiment, the lower left pad 350a may be disposed directly below the upper left pad 310a to face the upper left pad 310a. In addition, the lower right pad 350b may be disposed directly below the upper right pad 310b to face the upper right pad 310b. In other words, the lower left pad 350a and the upper left pad 310a may be disposed to overlap each other in the vertical direction, and the lower right pad 350b and the upper right pad 310b may be disposed to overlap each other in the vertical direction.

Referring to FIGS. 1 and 4A, the first redistribution lines 340a and 340b may be disposed on the upper surface 300S1 of the interposer 300. The first redistribution lines 340a and 340b may be disposed in pairs to be symmetrical with respect to the central axis Cy-300. As an example, the first redistribution lines 340a and 340b may be classified as first left redistribution lines 340a and first right redistribution lines 340b with respect to the central axis Cy-300. The first redistribution lines 340a and 340b may connect the second upper chip connection pads 320a and 320b to the wire bonding pads 330a and 330b, respectively. More specifically, the first redistribution lines 340a and 340b may be disposed between the second upper chip connection pads 320a and 320b and the wire bonding pads 330a and 330b while extending in the minor axis direction (i.e., the x-direction).

FIG. 5 is a schematic view illustrating a method of exchanging electrical signals between a semiconductor chip and a package substrate according to an embodiment of the present disclosure. In FIG. 5, the method of exchanging electrical signals is illustrated using the configuration of the lower chip 200, the interposer 300, and the upper chip 400 of the semiconductor package 1 described above with reference to FIGS. 1 to 4C. For the convenience of explanation, the package substrate 100 is not shown in FIG. 5.

Referring to FIG. 5, the electrical signal exchange between the upper chip 400 and the lower chip 200 may proceed as follows. As an example, an electrical signal output from the first upper chip left pad 410a of the upper chip 400 can reach the first lower chip right pad 210b through the second bump 530, the first upper left pad 310a, the second redistribution line 371, the first through via electrode 360a, the third redistribution line 381, the lower right pad 350b of the interposer 300, and the first bump 520. As such, the semiconductor package 1 may have an electrical signal path from the upper chip 400 to the lower chip 200. In addition, the semiconductor package 1 may have an electrical signal path from the lower chip 200 to the upper chip 400 in the opposite direction. The electrical signal path between the upper chip 400 and the lower chip 200 is shown as ‘F1’ in FIG. 5.

As another example, the electrical signal output from the first upper chip right pad 410b of the upper chip 400 can also reach the first lower chip left pad 210a through the second bump 530, the first upper right pad 310b, the third redistribution line 372, the second through via electrode 360b, the fourth redistribution line 382, the lower left pad 350a of the interposer 300, and the first bump 520. As such, the semiconductor package 1 may have an electrical signal path from the upper chip 400 to the lower chip 200. In addition, the semiconductor package 1 may have an electrical signal path from the lower chip 200 to the upper chip 400 in the opposite direction.

Referring to FIG. 5 with FIG. 1, the electrical signal exchange between the upper chip 400 and the package substrate 100 may proceed as follows. As an example, the electrical signal output from the second upper chip left pad 420a of the upper chip 400 can reach the left wire bonding pad 330a through the third bump 540, the second upper left pad 320a, and the first left redistribution line 340a of the interposer 300. The electrical signal reaching the left wire bonding pad 330a may be transmitted to the package substrate 100 through the left wire 50a of the bonding wires 50a and 50b. As such, the semiconductor package 1 may have an electrical signal path from the upper chip 400 to the package substrate 100. The electrical signals can be transmitted from the package substrate 100 to the upper chip 400 in the opposite direction. The electrical signal path between the upper chip 400 and the package substrate 100 is shown as “F2” in FIG. 5.

As another example, the electrical signal output from the second upper chip right pad 420b can also reach the right wire bonding pad 330b through the third bump 540, the second upper right pad 320b, and the first right redistribution line 340b of the interposer 300. The electrical signal reaching the right wire bonding pad 330b may be transmitted to the package substrate 100 through the right wire 50b of the bonding wires 50a and 50b.

As described above, the upper chip 400 might not be directly connected to the package substrate 100 through wire bonding. Instead, the upper chip 400 may be electrically connected to the wire bonding pads 340a and 340b disposed on the interposer 300, after the upper chip 400 is connected to the interposer 300 using bumps. Accordingly, the upper chip 400 may be electrically connected to the package substrate 100 through the bonding wires 50a and 50b bonded to the wire bonding pads 340a and 340b.

In addition, the lower chip 200 might not be directly connected to the package substrate 100 but may be electrically connected to the package substrate 100 via the upper chip 400. That is, the lower chip 200 might not directly have the wire bonding pad for wire bonding with the package substrate 100. The lower chip 200 may be connected to the upper chip 400 using the through via electrodes 360a and 360b of the interposer 300 and then electrically connect to the second upper chip pads 420a and 420b using inner wires of the upper chip 400. That is, the lower chip 200 may share the second upper chip pads 420a and 420b, which are the input/output pads of the upper chip 400, so that the lower chip 200 can exchange electrical signals with the package substrate 100 using the same path as the electrical signal path of the upper chip 400.

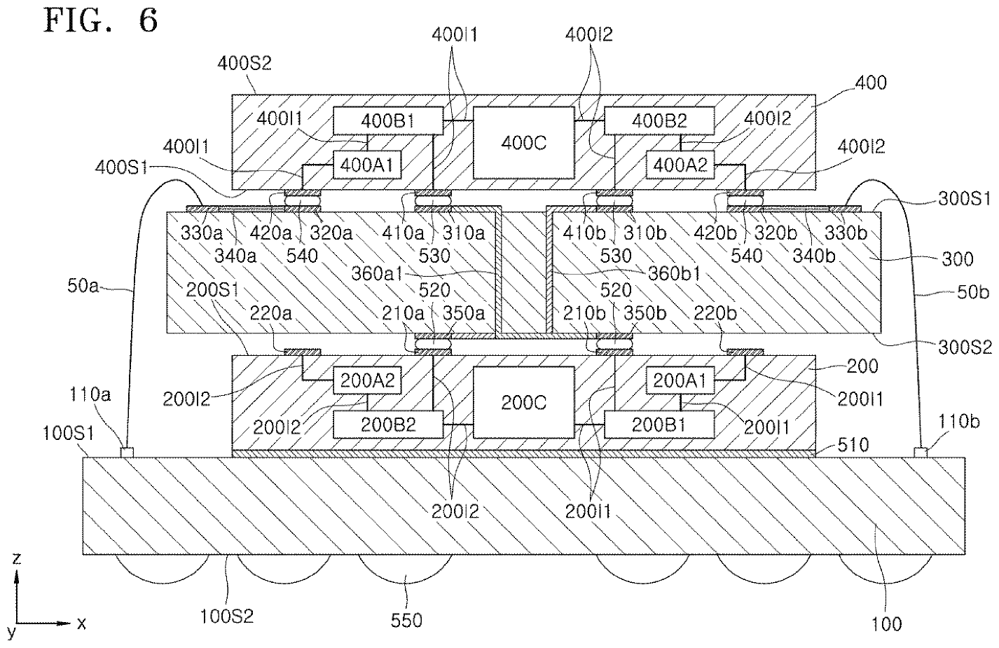

FIG. 6 is a view illustrating an internal circuit configuration of a semiconductor package according to an embodiment of the present disclosure. FIG. 6 may be a view schematically illustrating the internal circuit of the semiconductor package 1 described above with reference to FIG. 1.

Referring to FIG. 6, the package substrate 100 may include connection pads 110a and 110b disposed on an upper surface 10051 and connected by the boding wires 50a and 50b. In addition, the package substrate 100 may include connection structures 550 which are disposed on the lower surface 100S2 and provided for electrical connection with another semiconductor package or a printed circuit board.

The lower chip 200 may include first and second input/output circuit blocks 200A1 and 200A2, a first address and command circuit block 200B1, a first data transmission circuit block 200B2, and a first memory cell core block 200C. Likewise, the upper chip 400 may include third and fourth input/output circuit blocks 400A1 and 400A2, a second address and command circuit block 40061, a second data transmission circuit block 400B2, and a second memory cell core block 400C.

The interposer 300 disposed between the lower chip 200 and the upper chip 400 may include the lower chip connection pads 350a and 350b disposed on the lower surface 300S2 of the interposer 300 for connection with the lower chip 200. Moreover, the interposer 300 may include the first upper chip connection pads 310a and 310b and the second upper chip connection pads 320a and 320b disposed on the upper surface 300S1 of the interposer 300 for connection with the upper chip 400. In addition, the interposer 300 may include the wire bonding pads 330a and 330b for connection with the bonding wires 50a and 50b and may include first redistribution lines 340a and 340b for connecting the second upper chip connection pads 320a and 320b to the wire bonding pads 330a and 330b, respectively.

First, the electrical signal of the package substrate 100 may be input to the second upper chip pads 420a and 420b of the upper chip 400 via the connection pads 110a and 110b, the bonding wires 50a and 50b, the wire bonding pads 330a and 330b, the first redistribution lines 340a and 340b, the second upper chip connection pads 320a and 320b of the interposer 300, and the third bump 540. Among the input electrical signals, some input signals along a first upper chip internal wiring 400I1 of the input electrical signals may pass through the third input/output circuit block 400A1 and be converted into address and command signals by the second address and command circuit block 400B1, and then may be transferred to the second memory cell core block 400C. Moreover, among the input electrical signals, some other input signals along the second upper chip internal wiring 400I2 may pass through the fourth input/output circuit block 400A2 and be converted into data signals by the second data transmission circuit block 400B2, and then may be transferred to the second memory cell core block 400C.

Meanwhile, the first upper chip internal wiring 400I1 of the upper chip 400 may be connected to a first lower chip internal wiring 200I1 via the first upper chip pad 410a, the second bump 530, the first upper chip connection pad 310a of the interposer 300, the first internal wiring 360a1 of the interposer 300, which includes the through via electrode and the redistribution line, the lower chip connection pad 350b, the first bump 520 and the first lower chip pad 210b. Accordingly, among the electrical signals of the package substrate 100, some electrical signals output from the second address and command circuit block 400B1 of the upper chip 400 may be input to the lower chip 200. The electrical signals input to the lower chip 200 may be input to the first address and command circuit block 200B1 and converted into first address and command signals, and then, may be transferred to the first memory cell core block 200C, along the first lower chip internal wiring 200I1. As a result, the lower chip 200 can receive the electrical signals of the package substrate 100 via the upper chip 400 without the electrical signals passing through the second lower chip pad 220b, the first input/output circuit block 200A1, and the first address and command circuit block 200B1.

Likewise, the second upper chip internal wiring 400I2 of the upper chip 400 may be connected to the second lower chip internal wiring 200I2 via the first upper chip pad 410b, the second bump 530, the first upper chip connection pad 310b of the interposer 300, the second internal wiring 360b1 of the interposer 300, which includes the through via electrode and redistribution line, the lower chip connection pad 350a, the first bump 520, the first lower chip pad 210a. Accordingly, among the electrical signals of the package substrate 100, some electrical signals output from the second data transmission circuit block 400B2 of the upper chip 400 may be input to the lower chip 200. The electrical signals input to the lower chip 200 may be input to the first data transmission circuit block 200B2 and converted into data signals, and then, may be transferred to the first memory cell core block 200C, along the second lower chip internal wiring 200I2. As a result, the lower chip 200 can receive the electrical signals of the package substrate 100 via the upper chip 400 without the electrical signals passing through the second lower chip pad 220a, the second input/output circuit block 200A2, and the first data transmission circuit block 200B2.

Meanwhile, referring again to FIG. 6, the electrical signals output from the second data cell core block 400C of the upper chip 400 may pass through the second address and command circuit block 400B1 and the third input/output circuit block 400A1 along the first upper chip internal wiring 400I1, or may pass through the second data transmission circuit block 400B2 and the fourth input/output circuit block 400A2 along the second upper chip internal wiring 400I2, to reach the second upper chip pads 420a or 420b. Thereafter, the electrical signals may be output to the interposer 300 from the second upper chip pads 420a and 420b. And, the electrical signals may be transferred to the package substrate 100 from the interposer 300 through the bonding wires 50a and 50b.

In addition, the electrical signals output from the first data cell core block 200C of the lower chip 200 may reach the first upper chip connection pads 310a and 310b along the first and second lower chip internal wiring 200I1 and 200I2, the first and second interposer internal wirings 360a1 and 360b1, respectively. The signals may move along the first and second upper chip internal wirings 400I1 and 400I2 and reach the second upper chip pads 420a and 420b of the upper chip 400. Thereafter, the electrical signals may be output from the second upper chip pads 420a and 420b to the interposer 300, and then, may be transferred to the package substrate 100 via the bonding wires 50a and 50b.

The second lower chip pads 220a and 220b electrically connected to the first and second lower chip internal wirings 200I1 and 200I2 of the lower chip 200 might not be electrically connected to other structures outside the package. Accordingly, the lower chip 200 might not be electrically connected to other external chips, packages or substrates through the first and second input/output circuit blocks 200A1 and 200A2, except for the upper chip 400.

As described above, the embodiments of the present disclosure may provide semiconductor packages having a lower chip, an interposer, and an upper chip, which are sequentially stacked on a package substrate. In the semiconductor packages, the interposer may be connected to the package substrate by a bonding wire. The upper chip may be connected to the interposer by bumps and may be electrically connected to the package substrate via a redistribution line and the bonding wire. In addition, the upper chip may be electrically connected to the lower chip using a through via electrode inside the interposer.

According to the embodiments of the present disclosure, redistribution lines for connection with the package substrate can be omitted on the upper chip and the lower chip. Accordingly, generation of parasitic capacitance between the redistribution lines and the circuit pattern layers of the upper and lower chips may be reduced or suppressed. In addition, the upper chip may be configured to exchange electrical signals with the package substrate via the interposer, and the lower chip may be configured to exchange electrical signals with the package substrate via the upper chip. Accordingly, a direct electrical connection between the lower chip and the package substrate can be omitted, and as a result, the parasitic capacitance generated in the lower chip due to the input/output circuit involved in the electrical connection can be further reduced or suppressed.

Consequently, in the embodiments of the present disclosure, it is possible to provide a semiconductor package structure capable of improving the signal transmission speed of the semiconductor package through reduction or suppression of undesired parasitic capacitance occurring in the semiconductor chip stacked on the package substrate.

Embodiments of the present disclosure have been disclosed for illustrative purposes. Those skilled in the art will appreciate that various modifications, additions, and substitutions are possible, without departing from the scope and spirit of the present disclosure and the accompanying claims.

What is claimed is:

1. A stacked semiconductor package comprising:
a package substrate;
a lower chip, an interposer, and an upper chip sequentially stacked on the package substrate; and
bonding wires electrically connecting the package substrate and the interposer,
wherein the interposer comprises:
lower chip connection pads disposed on a lower surface of the interposer, wherein the lower chip connection pads are electrically connected to the lower chip;
first upper chip connection pads and second upper chip connection pads disposed on an upper surface of the interposer, wherein the first upper chip connection pads and the second upper chip connection pads are electrically connected to the upper chip;
wire bonding pads disposed on the upper surface of the interposer and bonded to the bonding wires;
first redistribution lines disposed on the upper surface of the interposer, the first redistribution lines electrically connecting the second upper chip connection pads to the wire bonding pads; and
through via electrodes electrically connecting the lower chip connection pads to the first upper chip connection pads.

2. The stacked semiconductor package of claim 1,
wherein the lower chip comprises first lower chip pads electrically connected to the lower chip connection pads;
wherein the lower chip comprises second lower chip pads disposed laterally adjacent to the first lower chip pads, wherein the second lower chip pads are not connected to the lower chip connection pads and are not connected to the package substrate, and
wherein the upper chip comprises first upper chip pads electrically connected to the first upper chip connection pads and second upper chip pads electrically connected to the second upper chip connection pads.

3. The stacked semiconductor package of claim 2, further comprising:
first bumps disposed between the first lower chip connection pads and the first lower chip pads;
second bumps disposed between the first upper chip connection pads and the first upper chip pads; and
third bumps disposed between the second upper chip connection pads and the second upper chip pads,
wherein the second bump and the third bump have substantially the same size.

4. The stacked semiconductor package of claim 2, wherein the first upper chip pad and the second upper chip pad have substantially the same size.

5. The stacked semiconductor package of claim 2,
wherein the upper chip is electrically connected to the package substrate through the interposer, and
wherein the lower chip is electrically connected to the package substrate by way of the through via electrodes of the interposer and the upper chip.

6. The stacked semiconductor package of claim 2,
wherein the lower chip comprises:
a first address and command circuit block electrically connected to a first lower chip pad of the first lower chip pads;
a first data transmission circuit block electrically connected to a second lower chip pad of the first lower chip pads;
a first input/output circuit block electrically connected to a first lower chip pad of the second lower chip pads and electrically connected to the first address and command circuit block;
a second input/output circuit block electrically connected to a second lower chip pad of the second lower chip pads and electrically connected to the first data transmission circuit block; and
a first memory cell core block electrically connected to the first address and command circuit block and electrically connected to the first data transmission circuit block, and
wherein the upper chip comprises:
a second address and command circuit block electrically connected to a first upper chip pad of the first upper chip pads;
a second data transmission circuit block electrically connected to a second upper chip pad of the first upper chip pads;
a third input/output circuit block electrically connected to a first upper chip pad of the second upper chip pads and electrically connected to the second address and command circuit block;
a fourth input/output circuit block electrically connected to a second upper chip pad of the second upper chip pads and electrically connected to the second data transmission circuit block; and
a second memory cell core block electrically connected to the second address and command circuit block and electrically connected to the second data transmission circuit block.

7. The stacked semiconductor package of claim 6,
wherein a first electrical signal from the package substrate is input to the third input/output circuit block through a first bonding wire of the bonding wires, a first wire bonding pad of the wire bonding pads, a first redistribution line of the first redistribution lines, a first upper chip connection pad of the second upper chip connection pads, and a first upper chip pad of the second upper chip pads,
wherein a second electrical signal from the package substrate is input to the fourth input/output circuit block through a second bonding wire of the bonding wires, a second wire bonding pad of the wire bonding pads, a second redistribution line of the first redistribution lines, a second upper chip connection pad of the second upper chip connection pads, and a second upper chip pad of the second upper chip pads,
wherein the first electrical signal is transferred to the second memory cell core block of the upper chip through the second address and command circuit block using internal wiring of the upper chip, and
wherein the second electrical signal is transferred to the second memory cell core block of the upper chip through the second data transmission circuit block using the internal wiring of the upper chip.

8. The stacked semiconductor package of claim 7,
wherein the first electrical signal from the package substrate is transferred to the second lower chip pad of the first lower chip pads,
wherein the second electrical signal from the package substrate is transferred to the first lower chip pad of the first lower chip pads,
wherein the first electrical signal is transferred to the first memory cell core block of the lower chip through the first address and command circuit bock using internal wiring of the lower chip, and
wherein the second electrical signal is transferred to the first memory cell core block of the lower chip through the first data transmission circuit bock using the internal wiring of the lower chip.

9. The stacked semiconductor package of claim 1, wherein the interposer comprises at least one region protruding laterally beyond a lateral edge of the upper chip.

10. The stacked semiconductor package of claim 9, wherein the wire bonding pads are disposed on the at least one laterally protruding region of the interposer.

11. The stacked semiconductor package of claim 1, wherein the first upper chip connection pads, the second upper chip connection pads, the wire bonding pads, the lower chip connection pads, and the through via electrodes are each disposed in a pair-symmetric manner with respect to a central axis of the interposer.

12. The stacked semiconductor package of claim 11,
wherein the interposer comprises a first upper left pad and a first upper right pad, which are symmetrical to each other with respect to the central axis of the interposer, as the first upper chip connection pads, and comprises a lower left pad located immediately below the first upper left pad and a lower right pad located immediately below the first upper right pad, as the lower chip connection pads, and
wherein the first upper left pad is electrically connected to the lower right pad through a first through via electrode, and the first upper right pad is electrically connected to the lower left pad through a second through via electrode.

13. The stacked semiconductor package of claim 12, wherein the interposer has a second redistribution line electrically connecting the first upper left pad to the first through via electrode and a third redistribution line electrically connecting the second through via electrode to the upper right pad, on the upper surface of the interposer, and has a fourth redistribution line electrically connecting the lower right pad to the first through via electrode and a fifth redistribution line electrically connecting the second through via electrode to the lower left pad, on the lower surface of the interposer.

14. A stacked semiconductor package comprising:
a package substrate;
a lower chip, an interposer, and an upper chip sequentially stacked on the package substrate; and
bonding wires electrically connecting the package substrate and the interposer,
wherein the interposer comprises:
through via electrodes electrically connecting the lower chip to the upper chip; and
first redistribution lines electrically connecting the upper chip to the bonding wires.

15. The stacked semiconductor package of claim 14,
wherein the upper chip is electrically connected to the package substrate through the interposer, and
wherein the lower chip is electrically connected to the package substrate by way of the through via electrodes of the interposer and the upper chip.

16. The stacked semiconductor package of claim 14,
wherein the interposer further comprises:
lower chip connection pads disposed on a lower surface of the interposer, wherein the lower chip connection pads are electrically connected to the lower chip;
first upper chip connection pads and second upper chip connection pads disposed on an upper surface of the interposer, wherein the first upper chip connection pads and the second upper chip connection pads are electrically connected to the upper chip; and
wire bonding pads disposed on the upper surface of the interposer and bonded to the bonding wires.

17. The stacked semiconductor package of claim 16,
wherein the through via electrodes electrically connect the lower chip connection pads to the first upper chip connection pads, and
wherein the first redistribution lines electrically connect the second upper chip connection pads to the wire bonding pads.

18. The stacked semiconductor package of claim 17, wherein the first upper chip connection pads, the second upper chip connection pads, the wire bonding pads, the lower chip connection pads, and the through via electrodes are each disposed in a pair-symmetric manner with respect to a central axis of the interposer.

19. The stacked semiconductor package of claim 18,
wherein the interposer comprises a first upper left pad and a first upper right pad, which are symmetrical to each other with respect to the central axis of the interposer, as the first upper chip connection pads, and comprises a lower left pad located immediately below the first upper left pad and a lower right pad located immediately below the first upper right pad, as the lower chip connection pads, and
wherein the first upper left pad is electrically connected to the lower right pad through a first through via electrode, and the first upper right pad is electrically connected to the lower left pad through a second through via electrode.

20. The stacked semiconductor package of claim 19,
wherein the interposer has a second redistribution line electrically connecting the first upper left pad to the first through via electrode and a third redistribution line electrically connecting the second through via electrode to the upper right pad, on the upper surface of the interposer, and has a fourth redistribution line electrically connecting the lower right pad to the first through via electrode and a fifth redistribution line electrically connecting the second through via electrode to the lower left pad, on the lower surface of the interposer.

21. The stacked semiconductor package of claim 16, wherein the wire bonding pads are disposed on regions of the interposer that extend laterally beyond edges of the upper chip.

22. The stacked semiconductor package of claim 16,
wherein the lower chip comprises first lower chip pads electrically connected to the lower chip connection pads and second lower chip pads disposed laterally adjacent to the first lower chip pads, wherein the second lower chip pads are not connected to the lower chip connection pads and are not connected to the package substrate, and
wherein the upper chip comprises first upper chip pads electrically connected to the first upper chip connection pads and second upper chip pads electrically connected to the second upper chip connection pads.

23. The stacked semiconductor package of claim 22, further comprising:
first bumps disposed between the lower chip connection pads and the first lower chip pads;
second bumps disposed between the first upper chip connection pads and the first upper chip pads; and
third bumps disposed between the second upper chip connection pads and the second upper chip pads,
wherein the second bump and the third bump have substantially the same size.

24. The stacked semiconductor package of claim 22, wherein the first upper chip pad and the second upper chip pad have substantially the same size.
